(19) United States
(12) Patent Application Publication
(10) Pub. No.: US 2007/0062670 A1
(43) Pub. Date: Mar. 22, 2007

(54) Casing with cooling means

(75) Inventors: Christiaan Radelet, Aarschot (BE); Peter Bos, Schoonderbuken (BE); Jean-Pierre Wandels, Koekelberg (BE); Bart Van Meeuwen, Zonhoven (BE); Joris Franckx, Bonheiden (BE); Chi Feng Hu, Taiwan (CN); Shu Lin Wang, Taiwan (CN); Li Chung Chen, Taiwan (CN); Kristof Vastmans, Boutersem (BE)

Correspondence Address: BAKER & DANIELS LLP, 300 NORTH MERIDIAN STREET, SUITE 2700, INDIANAPOLIS, IN, 46204, US

(73) Assignee: TYCO ELECTRNICS RAYCHEM NV, BELGIUM (BE)

(21) Appl. No.: 10/580,096

(22) PCT Filed: Nov. 12, 2004
(86) PCT No.: PCT/GB04/04767

§ 371 Date: May 19, 2006

(30) Foreign Application Priority Data
Nov. 19, 2003 (GB) 0326850.5
Oct. 19, 2004 (GB) 0423121.3

(51) Int. Cl. F24J 3/08; H05K 7/20

(52) U.S. Cl. 165/45; 361/704; 361/697

(57) ABSTRACT

A casing for containing apparatus which in use generates heat, the casing including a heat exchanger arranged to act as a removable wall (preferably a lid) of the casing, and fluid directing means arranged to be on the exterior of the said removable wall for directing a heat transfer fluid in thermal contact with the said wall in use, such that heat generated in the interior of the casing is transferred to the heat transfer fluid by conduction through the material of the said wall.

The present invention relates to casings for containing apparatus which in use generate heat. The invention finds particular application in casings which have been deployed in a confined underground environment, such as a manhole or a hand hole, in which thermal management is extremely important and presents a significant technical challenge. The present invention is particularly, although not exclusively, related to casings intended to house telecommunications equipment and the like comprising active electronic components and/or other elements that generate heat. Overheating of such casings is undesirable because it can lead to damage and inactivation of the telecommunications equipment or a reduction in its working lifetime. The present invention seeks to provide improvements in the cooling efficiency of such casings.

According to a first aspect of the present invention there is provided a casing for containing apparatus which in use generates heat, the exchanger comprising a wall capable of defining at least part of the exterior of the casing, and fluid directing means arranged to be on the exterior of the wall in use for directing a heat transfer fluid in thermal contact with the wall, such that heat generated in the interior of the casing is transferred to the heat transfer fluid through the wall. Accordingly, therefore, heat is transferred to the heat transfer fluid through the whole or a part of a wall of the casing. The wall of the casing forms part of the heat exchanger. The wall may be formed as a lid for the casing and the heat exchanger would therefore be easily accessible for maintenance and/or repair. The wall may be a removable member of the casing. By providing a wall which is removable the heat exchanger could be retrofitted to existing casings or formed as part of new casing.

The heat exchange may further comprise means for driving the heat transfer fluid to flow through the fluid directing means in order to enhance heat transfer. The fluid directing means may be defined at least in part by a plurality of upstanding ribs projecting from the exterior face of the wall. The ribs serve to increase the surface area of the fluid directing means to enhance heat transfer. Other formations, such as corrugations, could also be used to increase the efficiency of heat transfer.

The interior face of the wall may also be provided with a plurality of upstanding ribs in order to increase the surface area available within the interior of the casing for heated fluid to pass over and to exchange heat. The ribs may be offset with respect to the ribs on the exterior face in order to maximise the efficiency of heat transfer between the interior and exterior faces of the wall. Opposing faces of the exterior and interior ribs may be substantially co-linear such that there is substantially no overlap therebetween to maximise the efficiency of heat transfer.

The heat transfer fluid may be air. Air inlet and outlet pipes may then be provided to channel air to and from a heat transfer chamber incorporating the fluid directing means. There may be provided means for preventing water entering the pipes. Some form of anti-flooding provision is particularly important if the casing is to be sited outdoors and underground. In some embodiments the ends of the pipes remote from the heat transfer chamber may terminate with an air orifice which is orientated to point substantially downwards in use. For example, in one embodiment the pipes comprise inverted substantially L-shaped conduits. This creates a “bell-jar” effect either side of the heat transfer chamber to prevent flooding. The air inlet/outlet pipes may be arranged so that, in use, air enters/exists the pipes at a point lower than that at which it enters/exists the heat transfer chamber from the pipes.

This aspect of the present invention thus provides a casing for housing apparatus which in use generates heat, the casing having a heat exchanger as described above.

According to a further aspect of the present invention there is provided heat transfer means for assisting in cooling a casing housing apparatus which in use generates heat and is intended to be located in a confined chamber, the heat transfer means comprising a fluid-filled enclosure positionable between the exterior of the casing and the interior of the chamber for transferring heat from the casing to the chamber. By providing a fluid-filled enclosure the space between the exterior of the casing and the interior of the confined chamber can be spanned by the heat transfer means with greatly improved heat transfer efficiency over, for example, an air gap.

The heat transfer means may comprise a flexible, fluid-filled enclosure able to conform to the exterior shape of the casing and the interior shape of the chamber. By using a flexible enclosure the distance between the casing and the chamber does not have to be fixed. In addition, because the flexible enclosure can conform to the shape of the casing and the chamber, any irregularities in the shapes can be compensated for by the enclosure such that there is substantially complete contact between the enclosure and the opposing surfaces of the casing and the chamber to maximise the efficiency of heat transfer.

The heat transfer means may alternatively comprise a substantially rigid, fluid-filled tank. By using a rigid tank there is a decreased risk of damage to the integrity of the enclosure. The rigid tank could, for example, be placed in the confined chamber and act as a stand for the casing.

At least part of the tank may contact one or both of the exterior of the apparatus and the interior of the chamber indirectly via one or more heat transfer members. The heat transfer members may be located on the tank and/or on the exterior surface of the apparatus or the interior surface of the chamber. The heat transfer members may comprise upstanding fins which span between the tank and the chamber and/or the casing. Alternatively, at least part of the tank may contact one or both of the exterior of the apparatus and the interior of the chamber directly.

Any suitable fluid could be used for the fluid-filled enclosure. In one embodiment of the invention the fluid comprises distilled water. The fluid could be chosen on the basis of its thermal conductivity properties, ease of handling or cost. Distilled water is a good thermal conductor, is relatively cheap and is non-toxic which is an important consideration if the enclosure is to be placed in an underground chamber and there is a risk of leakage. An anti-freeze additive may be used to prevent the distilled water from freezing, particularly if the chamber is located outdoors. The fluid within the enclosure may be driven to circulate to increase the efficiency of heat transfer across the enclosure.

The present invention also provides a method of enhancing heat dissipation from a casing housing apparatus which in use generates heat and is intended to be placed within a confined chamber, comprising the step of positioning heat transfer means as described above between and in thermal contact with the exterior surface of the apparatus and the interior surface of the chamber. It is not essential that the enclosure is filled with fluid prior to positioning between the casing and the chamber. The enclosure could be positioned between the casing and the chamber and filled with fluid in situ. This could be particularly useful for an enclosure with a flexible wall where the spatial extent of the enclosure is determined by the amount of fluid inserted.

According to a further aspect of the present invention there is provided apparatus for use in transferring heat between spaced surfaces one of which forms at least part of an enclosure housing apparatus which in use generates heat, having means defining respective resiliently flexible surfaces each capable of conforming closely to the shape of the respectively spaced surfaces, and heat transfer means in thermal contact with both of the resiliently flexible surfaces. Typically the enclosure is a casing housing electronic equipment. The apparatus may be formed as a flexible enclosure housing fluid or, for example, could be formed as an unenclosed, self-supporting volume of thermally conductive material.

According to a still further aspect of the present invention there is provided a heat exchanging system for a casing housing apparatus which in use generates heat and is intended to be located in an underground chamber, the system comprising a heat transfer conduit for conducting a heat transfer fluid and adapted to receive heat from the casing, the heat transfer conduit being elongate and extending substantially linearly away from the casing, thereby reducing localised build-up of heat in the region of the casing resulting from heat dissipation.

It is known, for example, from WO 00/62590 to provide a heat exchanging system with coiled pipes extending from within the casing and out into a surrounding sub stratum to allow transfer of heat from the casing in to the substratum. However, the coiled pipes are positioned close to the casing and, moreover, serve to concentrate dissipated heat into a very small area of substratum. Accordingly heat dissipation from the coils is restricted.

By providing an elongate and linearly extending heat transfer conduit, heat dissipation is spread over a greatly increased mass of substratum and is mainly at a distance from the casing. Therefore, the local efficiency of heat dissipation of the heat transfer conduit does not have to be high because the heat dissipation occurs over a great length of conduit. The system results in a reduction of the thermal resistance between the conduit and the substratum, increasing the dissipation performance. The conduit may be in the form of a closed loop which extends away from and returns to the chamber. This therefore allows cycling of a volume of heat transfer fluid around the loop. The heat transfer conduit may extend from the underground chamber to a remote underground chamber. By underground chamber is meant, for example, a man hole or hand hole.

Whilst long lengths of heat transfer conduits are desirable, this presents a problem if digging of long trenches is required for their installation, as this increases costs. A conduit which is at least 10 metres in length, and preferably at least 30 metres, may be required in order to provide sufficient cooling for an average electronics apparatus casing. The present invention proposes to address this problem by routing the conduit through existing ducts which already extend from the chamber, for example the ducts which carry wiring or optical fibre networks between neighbouring man holes. In this way the present invention makes use of existing ducts and new ducts are not required to be installed in order to carry the conduit.

In embodiments where the conduit is a loop, the loop preferably extends away from the chamber in one duct and returns to the chamber in a different duct to minimise undesirable heat transfer between opposing sides of the loop. As an alternative, one side of the loop may be thermally insulated. Both sides of the loop can then be placed in the same duct. The heat exchanging system may further comprise driving means for driving the heat transfer fluid through the conduit in order to enhance heat dissipation.

The conduit may in alternative embodiments (not shown) comprise an elongated heat pipe arrangement in which a pipe is partially filled with liquid and has a porous inner surface. One end of the pipe is positioned next to the heat source. The heat causes evaporation of liquid and this removes heat. The evaporated liquid then rises towards the other end of the pipe. The other end of the pipe is in a cooler area and this causes the evaporated liquid to condense and run back down the pipe; the pipe is inclined upwards towards the other end to cause the condensed liquid to flow down towards the heat source.

In accordance with the invention, the same principles apply with a heat pipe as for a simple pipe. That is, the heat pipe is elongate and extends substantially linearly and extends away from the casing such that heat loss can occur over a large area of surrounding substratum, and such that heat from the casing does not inhibit heat loss from the pipe.

The present invention also provides a heat exchanging system for a casing housing apparatus which in use generates heat and is intended to be located in an underground chamber, the system comprising a heat transfer conduit for conducting a heat transfer fluid and adapted to receive heat from the casing, the heat transfer conduit extending between the chamber and a remote chamber.

As discussed above, a heat transfer conduit of considerable length is extremely useful in dissipating heat from a heat-generating apparatus. However, routing the conduit away from the casing presents some problems. The applicant has discovered that large lengths of heat transfer conduit can be routed between existing underground chambers. The route used for the conduit is advantageously existing ducts which already extend between the chambers. For example existing ducts carrying optical fibres joining the heat-generating apparatus together. The conduit may comprise a closed loop which extends between the chambers and the chambers themselves may be used to close the loops. For example, two open pipes can be passed between the chambers and a loop-back point can be added in the remote chamber. Alternatively, the remote chamber can itself comprise the loop-back. The system may further comprise driving means for driving the heat transfer fluid through the conduit in order to improve heat dissipation. As described above, a heat transfer conduit of at least 10 metres, and preferably 30 metres, is thought to be required for an average casing. As standard man holes/hand holes are spaced anywhere between 30 and several hundred metres apart they are seen as ideal points between which to route such heat transfer conduits.

The present invention will now be more particularly described, by way of example, with reference to the accompanying drawings, in which:

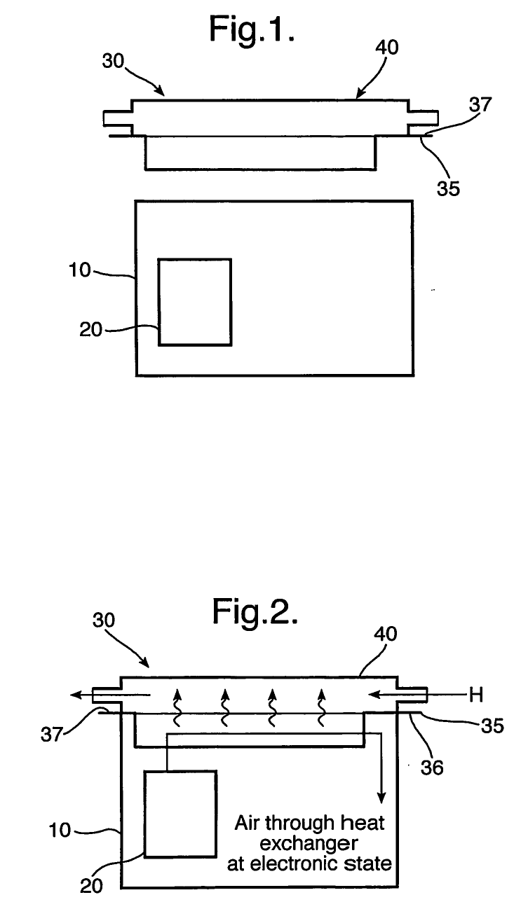

FIG. 1 is a diagrammatic representation of a heat exchanger and an associated casing according to a first aspect of the present invention;

FIG. 2 is a diagrammatic representation of the heat exchanger of FIG. 1 assembled on to the casing and in use;

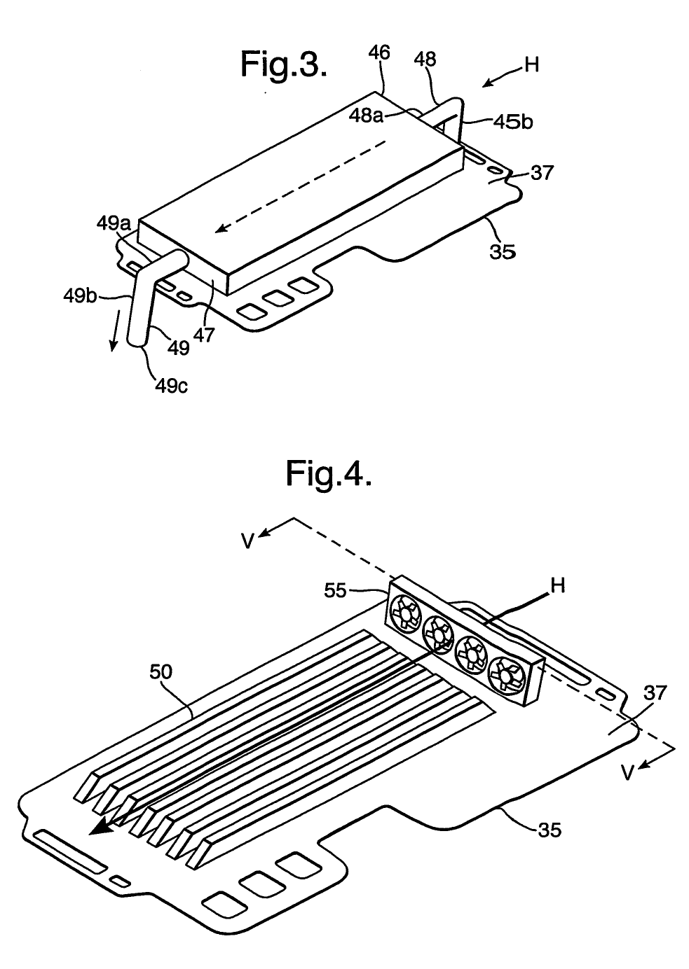

FIG. 3 is a perspective view of a heat exchanger of the type shown in FIG. 1;

FIG. 4 is a perspective view of the heat exchanger of FIG. 3 shown with a lid component removed in order to display the internal structure of the exchanger;

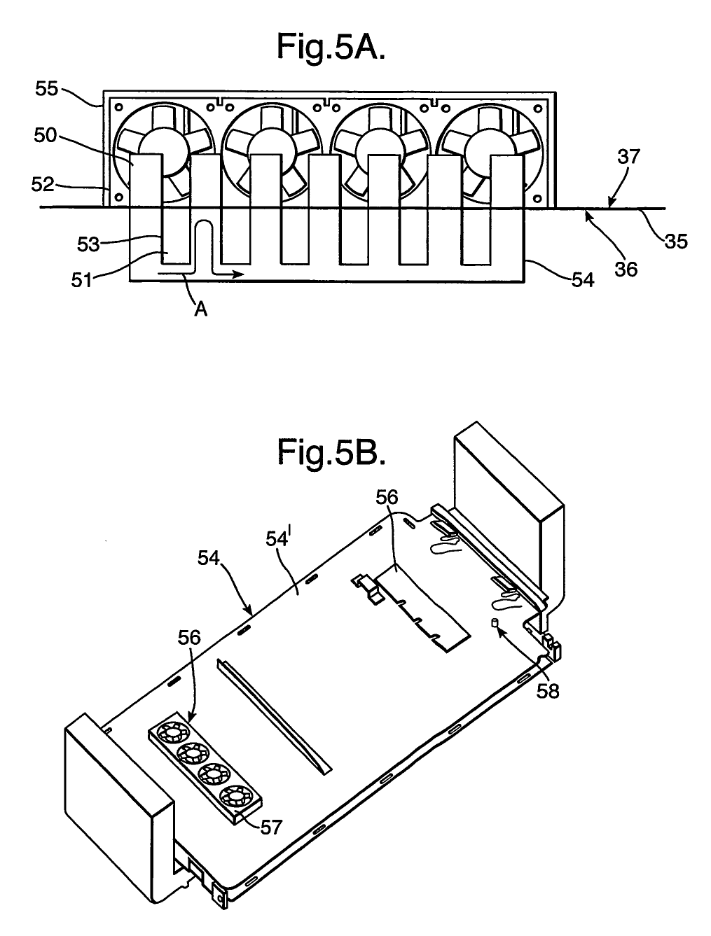

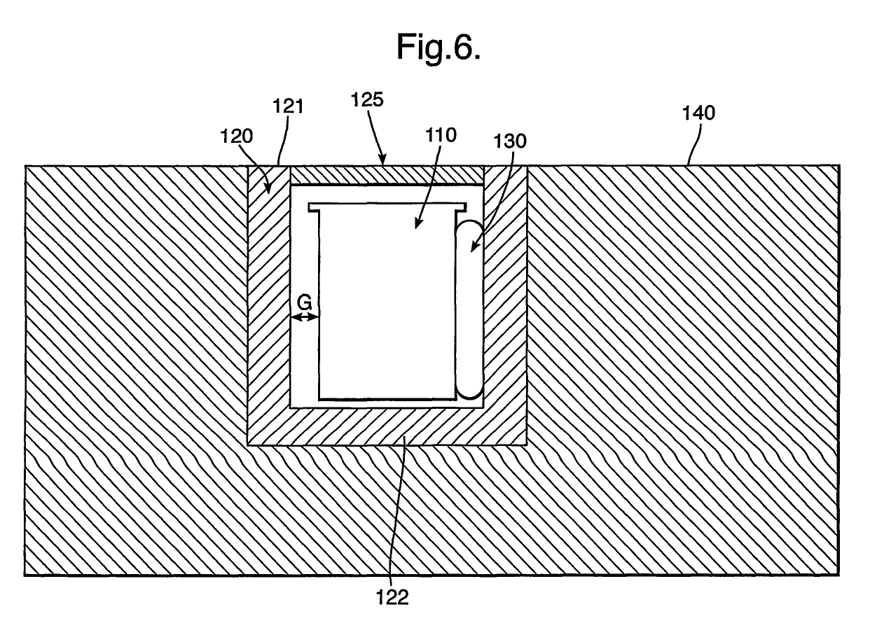

FIG. 5A is a section taken along line V-V of FIG. 4 and FIG. 5B shows an advantageous alternative arrangement;

FIG. 6 is a diagrammatic view showing heat transfer means for assisting in cooling a casing, according to a further aspect of the present invention;

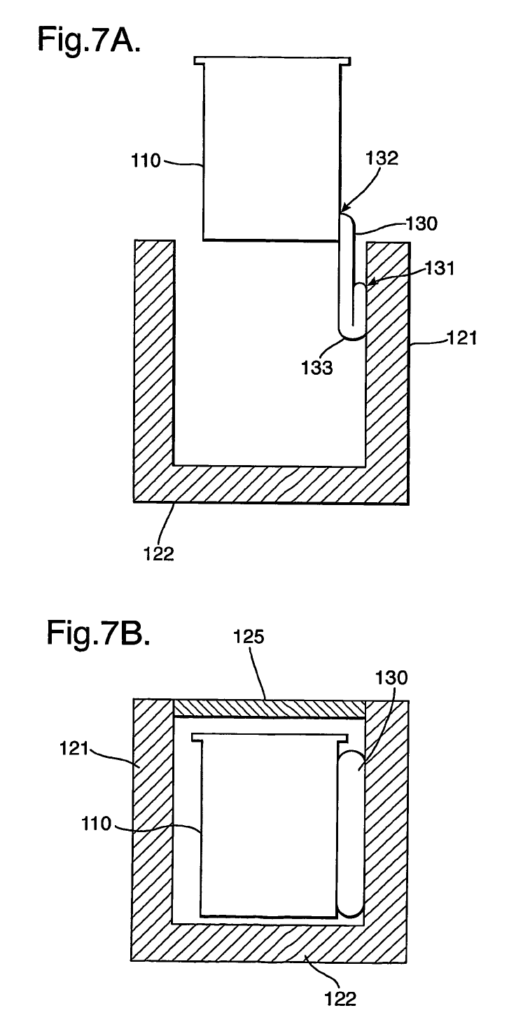

FIG. 7a is a diagrammatic representation of heat transfer means of the type shown in FIG. 6 associated with a casing prior to insertion into a confined chamber;

FIG. 7b shows the heat transfer means of FIG. 7a following insertion of the casing into the confined chamber.

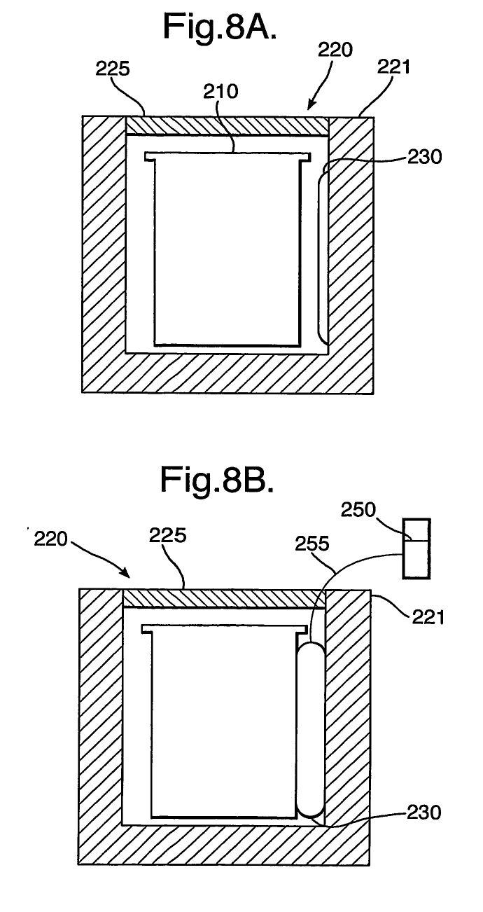

FIG. 8a is a diagrammatic representation of heat transfer means according to an alternative embodiment in which an enclosure is positioned prior to filling with fluid;

FIG. 8b shows the enclosure of FIG. 8a being filled with fluid;

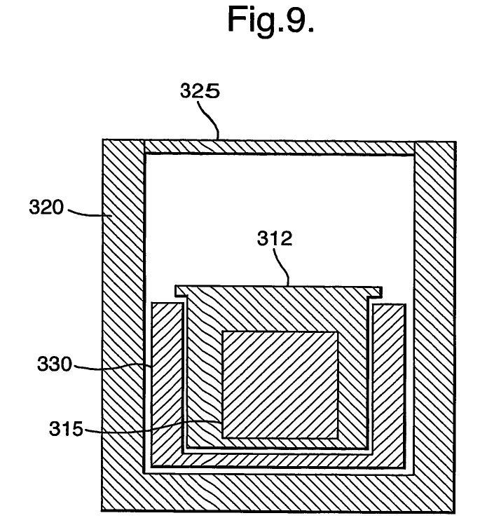

FIG. 9 is a diagrammatic representation of heat transfer means according to a further embodiment;

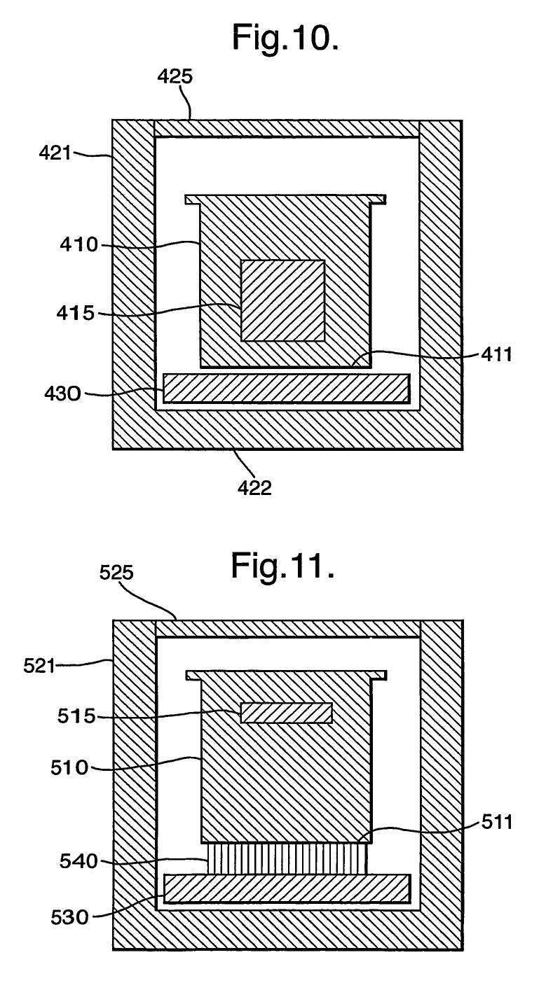

FIG. 10 is a diagrammatic representation of heat transfer means according to a further embodiment;

FIG. 11 is a diagrammatic representation of heat transfer means according to a further embodiment;

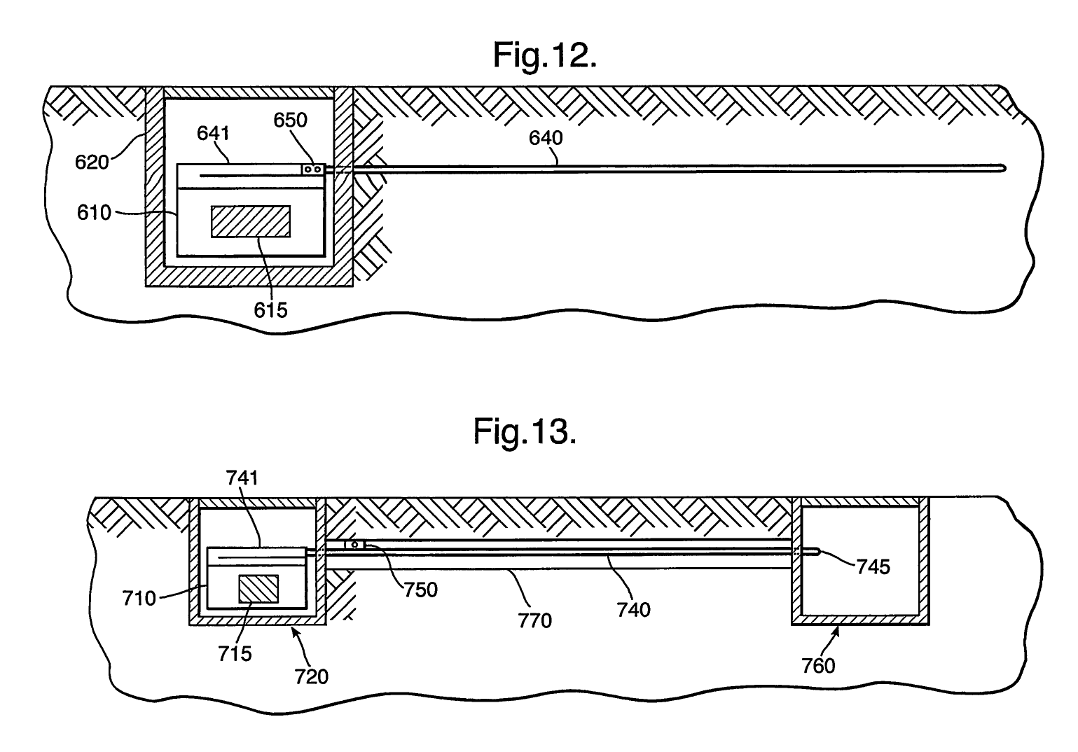

FIG. 12 illustrates diagrammatically a heat exchange system according to a further aspect of the present invention; and

FIG. 13 illustrates diagrammatically an alternative heat exchange system.

Referring first to FIG. 1 there is shown a casing generally indicated 10 which houses apparatus 20 which in use generates heat. A heat exchanger for the casing is generally indicated 30. The heat exchanger 30 comprises a wall 35 which is formed as a lid for the casing 10. The exchanger further comprises fluid directing means generally indicated 40 which are arranged to be on the exterior surface 37 of the wall 35 in use.

Referring now also to FIG. 2 the heat exchanger 30 is shown positioned on the casing 10 in order to close it. In use of the heat-generating apparatus 20 fluid, in this case air, surrounding the apparatus 20 within the casing 10 is heated. As the heated air circulates within the casing 10 it passes into contact with the interior surface 36 of the wall 35. Heat transfer fluid H is driven to flow through the fluid directing means 40 as described in more detail below. Accordingly heat is transferred from the interior of the casing 10 through the wall 35 to the exterior surface 37 of the wall 35 and into the heat transfer fluid which removes the heat as it is driven away from the heat exchanger 30. In this embodiment the heat transfer fluid H is air; however, any other suitable fluid, such as water, could be used.

Referring now to FIGS. 3 to 5 the heat exchanger 30 is illustrated in more detail.

The wall 35 comprises a generally rectangular plate. On the exterior surface 37 of the wall 35 is positioned a cover 45 of a generally upturned tray configuration. The cover 45, together with the upper surface 37 of the wall 35, defines a heat transfer chamber which houses a plurality of spaced ribs 50 which are upstanding from the exterior surface 37 (see FIG. 4).

Heat transfer fluid H enters the heat transfer chamber in which the ribs 50 are located via an inlet pipe 48 which is connected to one of the shorter sidewalls 46 of the cover 45. Heat transfer fluid exits the chamber via an outlet pipe 49 connected to the opposite side wall 47 of the cover 45.

The inlet and outlet pipes 48, 49 include a first leg portion 48a, 49a connected directly to the respective cover sidewalls 46, 47 and extending parallel to the major axis of the cover 45. At the ends of the portions 48a, 49a remote from the cover 45, second leg portions 48b, 49b extend downwards, orthogonally to the portions 48a, 49a, to create upturned L-shaped pipes 48, 49 terminating with air entrance and exit points 48c, 49c.

This arrangement means that the air entry 48c and exit 49c points are oriented to point downwards and present a flat orifice; in addition they are both below the level of the point of connection of the leg portions 48a, 49a to the heat transfer chamber. Accordingly a “bell-jar” effect is created which prevents water entering the chamber; this is essential if the system is to operate underground and in an outside environment. Other anti-flooding features could be added, such as valves or water traps.

It can be seen that heat transfer fluid H passes from the inlet 48 through fans 55 located on the exterior surface 37 of the wall next to the entry point of the inlet pipe 48, which drives the heat transfer fluid to pass between and over the ribs 50.

Referring to FIG. 5 it will be seen that on the interior surface 36 of the wall 35 are a series of downwardly depending spaced ribs 51 which are positioned to be offset with respect to the ribs 50. It will be noted that opposing exterior sidewalls 52,53 of the exterior and interior ribs 50,51 respectively are substantially co-linear. The ribs 51 are housed within a cover tray 54, which is open at both ends to allow heated air A to flow through the channel it creates around the ribs 51.

Alternatively, as shown in FIG. 5B, the cover tray 54 (with or without the ribs 51) may have closed ends together with apertures 56 in its innermost wall 54′ for entry and exit of the heated air (A) circulating within the casing. Propulsion units, preferably fan units 57, may conveniently, and preferably removably, be provided, for example by snap-fitting into one of the apertures 56, for assisting the flow of the heated air through the cover tray 54 and thus advantageously enhancing the efficiency of the heat exchange. A power cable for the fan unit 57 may enter the tray 54 through a suitable feedthrough 58, preferably having a heat-shrink seal of the kind known per se.

It will be seen that heated air A circulates around the internal ribs 51 and heat is transferred both from the ribs 51 and the spaces between the ribs 51 through the wall 35 to the exterior face 37 of the wall 35. From here the heat which collects on the ribs 50 and between the ribs 50 is transferred to the heat transfer fluid H as it moves from the inlet 48 through to the outlet 49 at which point heated heat transfer fluid is removed. The heated heat transfer fluid H may then be vented for example in an overground exhaust, or cooled in someway and recycled back into the inlet 48.

The offset arrangement of the ribs 51, 52 provides the optimal arrangement for heat transfer from the interior to the exterior face of the wall 35.

Referring now to FIG. 6 there is shown an alternative aspect of the present invention. A casing generally indicated 110 houses apparatus which in use generates heat (not shown). The casing 110 is located in a confined chamber 120, in this embodiment being a manhole. The confined chamber 120 comprises concrete sidewalls 121 and a concrete base 122. The chamber is closed by a lid in the form of a metal plate 125. An air gap indicated G exists between an exterior side wall of the casing 110 and the interior of the manhole 120. In order for heat to disperse from the casing it must pass through the air gap G, which is not an efficient conductor of heat. However, according to the present invention a fluid-filled enclosure 130 is positioned between an exterior wall of the casing 110 and the interior of the chamber 120. The enclosure 130 provides a heat transfer path from the casing 110 to the side walls 121 of the manhole 120 of increased conductivity, and therefore enhances heat removal from the casing 110. Once the heat has passed from the casing 110 through the enclosure 130 and into the walls 121, 122 of the chamber 120 it can then be dissipated into the surrounding substratum 140.

Referring now to FIGS. 7a and 7b there is shown one method of positioning the enclosure 130 between the casing 110 and the chamber wall 121. The enclosure 130 is an elongate bag one end 131 of which is attached to the bottom of the casing 110. The opposite end 132 of the enclosure 130 is connected towards the end of one of the sidewalls 121 opposite the base 122. As the casing 110 is lowered into the chamber 120 the enclosure 130 begins to form into a U-shape. The bottom 133 of the U-shape then rolls down the sidewall 121 until the casing 110 reaches the base 122. As it does so the enclosure is compressed between the casing 110 and the sidewall 121 and is caused to conform closely to the two opposing surfaces.

FIGS. 8a and 8b show an alternative embodiment in which an empty enclosure 230 is inserted between the exterior of the casing 210 and the interior of the chamber 220. The enclosure 230 may be adhered to the sidewall 221 prior to lowering the casing 210. Once the casing 210 has been lowered into position the enclosure 230 is filled with fluid 250 by inserting a pipe 255 through an opening in the lid 225 and into a suitable valve member (not shown) in the enclosure 230.

FIG. 9 shows alternative heat transfer means very similar to those shown in FIGS. 6 to 8. Whereas in FIGS. 6 to 8 the enclosure 130, 230 is positioned along one side of the casing, in this alternative embodiment the enclosure 330 is U-shape in section and therefore the casing 310 can be placed within the interior space created by the U-shape. In this way all surfaces of the casing 310 in proximity to an interior surface of the chamber 320 benefit from enhanced heat transfer provided by the enclosure. Of course an enclosure could also extend on to or be placed on to the casing lid 312 if required.

It will be noted that one or a plurality of the flexible enclosures of FIGS. 6 to 9 could be used to extend over the whole or part of a casing depending on their size and shape.

FIG. 10 shows an alternative embodiment in which a casing 410 houses apparatus 415 which in use generates heat. The casing 410 is located in a confined chamber 420, in this embodiment being a hand hole. The main chamber 420 comprises concrete side walls 421 and a concrete base 422. The chamber 420 is closed by a lid in the form of a metal plate 425. The casing 410 is positioned so that its base 411 rests on a self-supporting, fluid-filled enclosure 430. The enclosure 430 is in turn positioned to rest on the base 422 of the chamber 420. Heat passes from the casing 410 to the enclosure 430 and then to the chamber walls 421, 422 before passing into the surrounding substratum.

FIG. 11 shows a further embodiment very similar to that shown in FIG. 10 except that the casing base 511 includes a plurality of depending fins 540 upon which the casing 510 stands in contact with the enclosure 530. The fins 540 promote heat transfer from the casing 510 to the enclosure 530. Heat passes from the casing to the enclosure 530 and then to the chamber walls 521, 522 before passing into the surrounding substratum.

Referring now to FIG. 12 there is shown a heat exchanging system according to a further aspect of the present invention.

A casing 610 is provided and houses apparatus 615 which in use generates heat The casing 610 is tended to be located in an underground chamber 620 such as a manhole. In order to remove heat generated by the apparatus 615 from the casing 610 a heat exchanger is provided in the form of a heat transfer conduit 640. The heat conduit 640 contains a heat transfer fluid, such as water. The conduit 640 is arranged to receive heat from the casing 610. This can be achieved, for example, by passing the conduit directly through the casing 610 or, as in this embodiment, via an external heat exchange compartment 641.

The heat transfer conduit 640 is in the form of a loop. The conduit 640 is elongated and extends with a linear path. The heat transfer fluid is driven around the loop by a fan, pump or the like 650. Typically a fan 650 is integrated into the heat exchanger 641.

The loop 640 is buried into the surrounding substratum such that as the heat transfer fluid moves around the loop it collects heat in the heat exchanger 641 and then dissipates heat into the surrounding substratum as it passes around the loop. Because the loop has a rectilinear path heat dissipation into the surrounding substratum is not concentrated at any one particular point but rather occurs gradually over the considerable length of the loop. Accordingly the thermal resistance of the surrounding substratum is not a limiting factor in heat dissipation as it would be if the conduit, and thus heat dissipation, was concentrated, for example by coiling.

Referring now to FIG. 13 there is shown an alternative embodiment similar to that shown in FIG. 12 in that there is a casing 710 housing heat-generating apparatus 715 and a heat-exchanging loop 740 is provided to receive heat from the casing 710. Once again the heat transfer conduit extends with a rectilinear path. In this embodiment the conduit loop 740 extends from the chamber 720 to a remote chamber 760. In practice the distance between the neighbouring chambers 720, 760 can be anywhere between 30 to 500 meters.

A further difference in this system is that the path used to install the conduit is an existing duct 770 which already extends between the two chambers 720, 760. By utilising an existing duct a new duct required specifically for the loop is not required. In practice the loop could be established by passing two straight conduits down a duct from the chamber 720 to the remote chamber 760 and then adding a U-shape loop-back 745 at the remote chamber 760.

In an alternative embodiment (not shown) the upstream and downstream arms of the loop are passed through different ducts to prevent heat transfer between the two.

1. A casing for containing apparatus which in use generates heat, the casing including a heat exchanger arranged to act as a removable wall of the casing, and fluid directing means arranged to be on the exterior of the said removable wall for directing a heat transfer fluid in thermal contact with the said wall in use, such that heat generated in the interior of the casing is transferred to the heat transfer fluid by conduction through the material of the said wall.

2. A casing as claimed in claim 1, wherein the heat transfer fluid is air and in which air inlet and outlet pipes are provided to channel air to and from a heat transfer chamber incorporating the fluid directing means

3. A casing as claimed in claim 2, wherein there are provided means for preventing water from entering the pipes.

4. A casing as claimed in claim 3, wherein the ends of the pipes remote from the heat transfer chamber terminate with an air orifice which is orientated to point substantially downwards in use.

5. A casing as claimed in claim 1, wherein the inlet/outlet pipes are arranged so that, in use, air enters/exits the pipes at a point lower than that at which it enters/exits the heat transfer chamber.

6. A casing as claimed in claim 1, further comprising means for driving the heat transfer fluid to flow through the fluid directing means.

7. A casing as claimed in claim 1, wherein the wall is a lid and carries, on its surface remote from the said fluid directing means, a channel for circulation of heated air within the casing in use and the channel includes at least one propulsion means for assisting the circulation of the air through the said channel.

8. A casing according to claim 7, wherein the propulsion means is a fan unit removably mounted in an aperture in the wall of the said channel which is innermost within the casing in use.

9. A casing as claimed in claim 1, wherein the fluid directing means are defined at least in part by a plurality of upstanding ribs projecting from the exterior face of the wall.

10. A casing as claimed in claim 9, wherein the interior face of the wall has a plurality of upstanding ribs offset with respect to the ribs on the exterior face.

11. A heat exchanger as claimed in claim 10, wherein the opposing faces of the exterior and interior ribs are substantially co-linear.

12. A casing for housing apparatus which in use generates heat, the casing having a heat exchanger as claimed in claim 1.

13-42. (canceled)
